(19) United States
(12) Patent Application Publication
(10) Pub. No.: US 2022/0415835 A1
(43) Pub. Date: Dec. 29, 2022

(54) SEMICONDUCTOR PACKAGE AND METHOD OF FABRICATING THE SAME

(71) Applicant: Samsung Electronics Co., Ltd., Suwon-si (KR)

(72) Inventors: Minjun BAE, Yongin-si (KR); Seokhyun LEE, Hwaseong-si (KR); Eungkyu KIM, Yongin-si (KR)

(73) Assignee: Samsung Electronics Co., Ltd., Suwon-si (KR)

(21) Appl. No.: 17/742,852

(22) Filed: May 12, 2022

(30) Foreign Application Priority Data
Jun. 25, 2021 (KR) 10-2021-0083368

(51) Int. Cl. H01L 23/00

(52) U.S. Cl. CPC H01L 24/05; H01L 24/03; H01L 2224/0231; H01L 2224/0239; H01L 2224/024; H01L 2224/04042

(57) ABSTRACT

Disclosed are semiconductor packages and their fabricating methods. A semiconductor package includes a semiconductor chip on a redistribution substrate. The redistribution substrate includes a base dielectric layer and upper coupling pads in the base dielectric layer. Top surfaces of the upper coupling pads are coplanar with a top surface of the base dielectric layer. The semiconductor chip includes a redistribution dielectric layer and redistribution chip pads in the redistribution dielectric layer. Top surfaces of the redistribution chip pads are coplanar with a top surface of the redistribution dielectric layer. The top surface of the redistribution dielectric layer is bonded to the top surface of the base dielectric layer. The redistribution chip pads are bonded to the upper coupling pads. The redistribution chip pads and the upper coupling pads include a same metallic material. The redistribution dielectric layer and the base dielectric layer include a photosensitive polymer layer.

### CROSS-REFERENCE TO RELATED APPLICATION

This U.S. nonprovisional application claims priority under 35 U.S.C § 119 to Korean Patent Application No. 10-2021-0083368 filed on Jun. 25, 2021 in the Korean Intellectual Property Office, the disclosure of which is hereby incorporated by reference in its entirety.

### BACKGROUND

Inventive concepts relate to a semiconductor package and/or a method of fabricating the same, and more particularly, to a semiconductor package with increased integration and improved reliability and/or a method of fabricating the same.

A semiconductor package may be provided to implement an integrated circuit chip for use in electronic products. Typically, the semiconductor package includes a semiconductor chip mounted on a printed circuit board (PCB) and bonding wires or bumps may be used to electrically connect the semiconductor chip to the printed circuit board. With the development of electronic industry, various studies have been conducted to improve reliability and durability of semiconductor packages.

### SUMMARY

Some embodiments of inventive concepts provide a semiconductor package with increased integration and improved reliability and/or a method of fabricating the same.

According to some embodiments of inventive concepts, a semiconductor package may include a redistribution substrate, a semiconductor chip on the redistribution substrate, a molding layer, and a plurality of connection terminals. The redistribution substrate may include a base dielectric layer, a plurality of lower coupling pads on a bottom surface of the base dielectric layer, a plurality of upper coupling pads in the base dielectric layer, and a plurality of redistribution patterns that connect the plurality of lower coupling pads and the upper coupling pads to each other in the base dielectric layer. Top surfaces of the upper coupling pads may be coplanar with a top surface of the base dielectric layer. The semiconductor chip may include a semiconductor substrate that includes a plurality of chip pads, a protection layer that covers a top surface of the semiconductor substrate, a redistribution dielectric layer on the protection layer, and a plurality of redistribution chip pads that penetrate the redistribution dielectric layer and the protection layer and are connected to the plurality of chip pads. Top surfaces of the plurality of redistribution chip pads may be coplanar with a top surface of the redistribution dielectric layer. The molding layer may be on a top surface of the redistribution substrate and may cover the semiconductor chip. The plurality of connection terminals may be on a bottom surface of the redistribution substrate and may be connected to the plurality of lower coupling pads. The top surface of the redistribution dielectric layer may be bonded to the top surface of the base dielectric layer. The redistribution chip pads may be bonded to the plurality of upper coupling pads. Each of the plurality of redistribution chip pads may have an inclined first sidewall and a first top surface that may have a first maximum width. Each of the plurality of upper coupling pads may have an inclined second sidewall and a second top surface that may have a second maximum width. The second top surface may be directly coupled to the first top surface. The first maximum width and the second maximum width may have a range of about 20 μm to about 70 μm.

According to some embodiments of inventive concepts, a semiconductor package may include a redistribution substrate and a semiconductor chip on the redistribution substrate. The redistribution substrate may include a base dielectric layer and a plurality of upper coupling pads in the base dielectric layer. Top surfaces of the plurality of upper coupling pads may be coplanar with a top surface of the base dielectric layer. The semiconductor chip may include a redistribution dielectric layer and a plurality of redistribution chip pads in the redistribution dielectric layer. Top surfaces of the plurality of redistribution chip pads may be coplanar with a top surface of the redistribution dielectric layer. The top surface of the redistribution dielectric layer may be bonded to the top surface of the base dielectric layer. The plurality of redistribution chip pads may be bonded to the plurality of upper coupling pads. The plurality of redistribution chip pads and the plurality of upper coupling pads may include a same metallic material. The redistribution dielectric layer and the base dielectric layer may include a photosensitive polymer layer.

According to some embodiments of inventive concepts, a semiconductor package may include a redistribution substrate and a semiconductor chip on the redistribution substrate. The redistribution substrate may include a base dielectric layer and a plurality of upper coupling pads in the base dielectric layer. The semiconductor chip may include a semiconductor substrate that includes a plurality of chip pads, a protection layer that covers a top surface of the semiconductor substrate, a redistribution dielectric layer on the protection layer, and a plurality of redistribution chip pads that penetrate the redistribution dielectric layer and the protection layer and are connected to the plurality of chip pads. The base dielectric layer and the redistribution dielectric layer may be in direct contact with each other. The plurality of redistribution chip pads and the plurality of upper coupling pads may be in direct contact with each other. Each of the redistribution chip pad and the plurality of upper coupling pad may have an inclined sidewall. Each of the plurality of redistribution chip pads may have a first maximum width at a bonding surface between the redistribution substrate and the semiconductor chip. Each of the plurality of upper coupling pads may have a second maximum width at the bonding surface between the redistribution substrate and the semiconductor chip.

According to some embodiments of inventive concepts, a method of fabricating a semiconductor package may include forming a first substrate that includes a plurality of semiconductor chips, each of the plurality of semiconductor chips including a plurality of chip pads; forming a redistribution dielectric layer that covers a top surface of the first substrate; forming in the redistribution dielectric layer a plurality of redistribution chip pads connected to the plurality of chip pads, top surfaces of the plurality of redistribution chip pads being coplanar with a top surface of the redistribution dielectric layer; after forming the plurality of redistribution chip pads, cutting the first substrate to separate the plurality of semiconductor chips from each other; forming a redistribution substrate that includes a base dielectric layer and a plurality of upper coupling pads in the base dielectric layer, top surfaces of the plurality of upper coupling pads being coplanar with a top surface of the base dielectric layer; and establishing a hybrid bonding between the redistribution substrate and the plurality of semiconductor chips such that the plurality of redistribution chip pads of the plurality of semiconductor chips directly contact the plurality of upper coupling pads of the redistribution substrate, and the base dielectric layer directly contacts the redistribution dielectric layer.

Details of other example embodiments are included in the description and drawings.

### BRIEF DESCRIPTION OF THE DRAWINGS

The above and other features and advantages of example embodiments of the inventive concept will become more apparent by describing them in detailed with reference to the accompanying drawings.

FIG. 1 illustrates a cross-sectional view showing a semiconductor package according to some embodiments of inventive concepts.

FIGS. 2A, 2B, 2C, and 2D illustrate enlarged cross-sectional views showing section P of FIG. 1.

FIGS. 3 to 7 illustrate cross-sectional views showing a semiconductor package according to some embodiments of inventive concepts.

FIGS. 8 to 18 illustrate cross-sectional views showing a method of fabricating a semiconductor package according to some embodiments of inventive concepts.

### DETAILED DESCRIPTION OF EMBODIMENTS

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The following will now describe a semiconductor package and a method of fabricating the same according to some embodiments of inventive concepts in conjunction with the accompanying drawings.

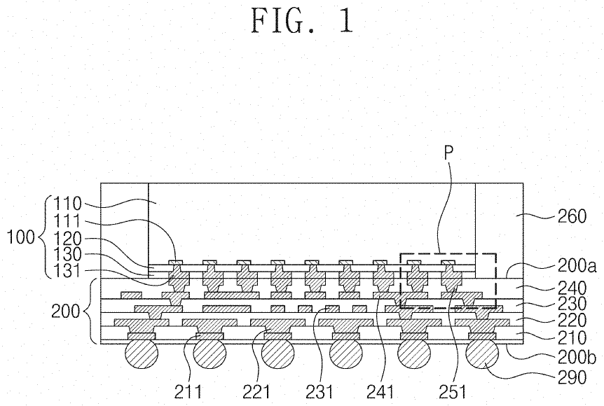

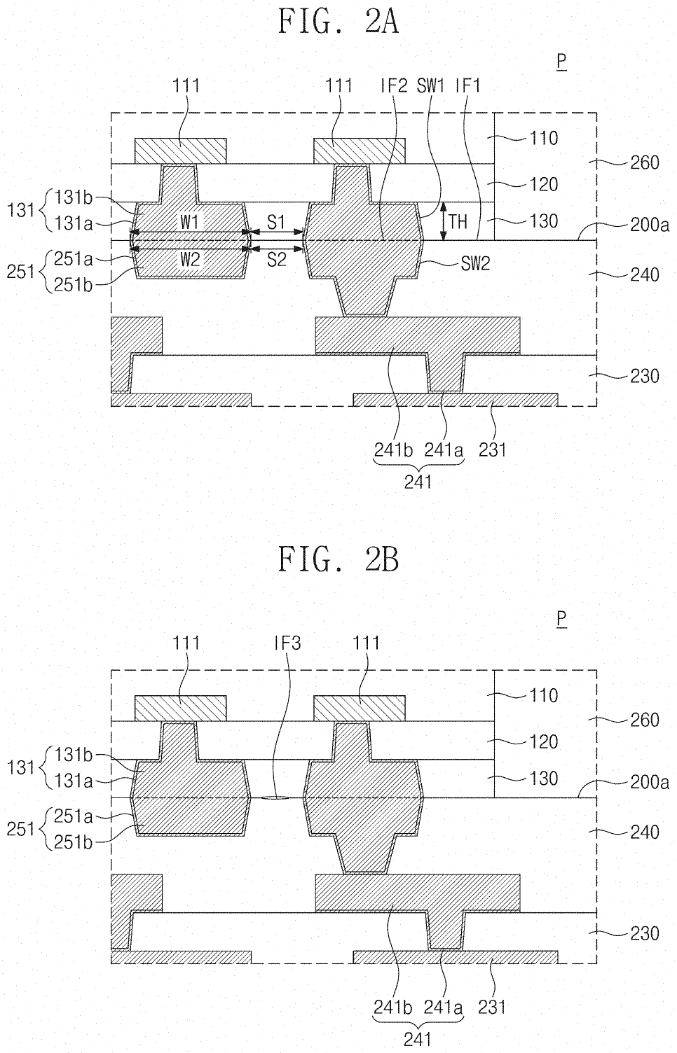

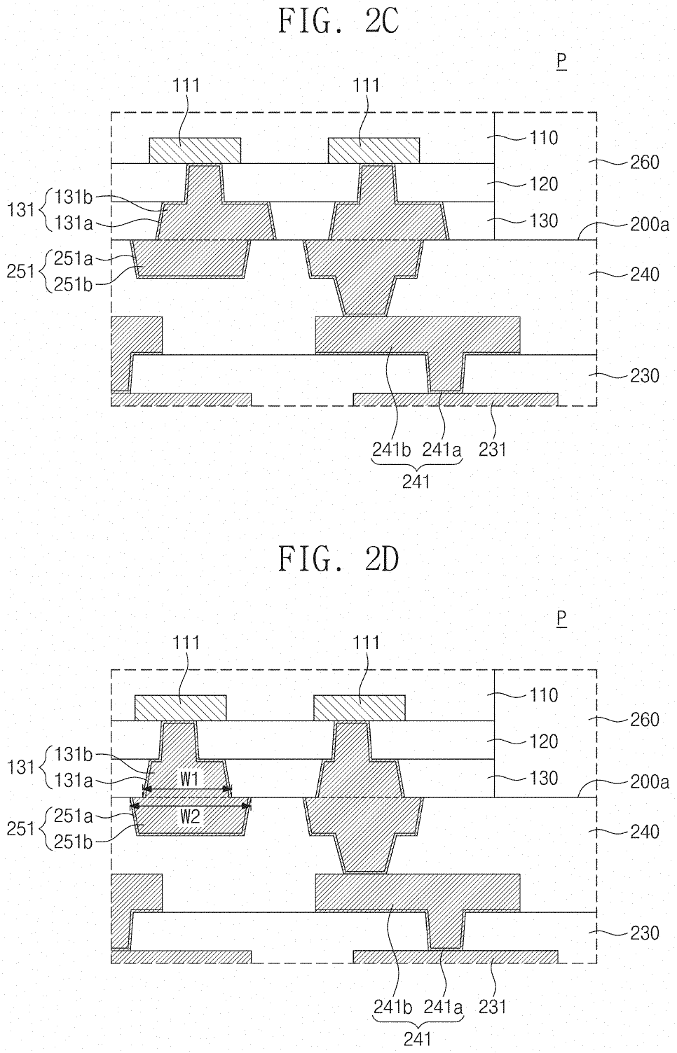

FIG. 1 illustrates a cross-sectional view showing a semiconductor package according to some embodiments of inventive concepts. FIGS. 2A, 2B, 2C, and 2D illustrate enlarged cross-sectional views showing section P of FIG. 1.

Referring to FIGS. 1 and 2A, a semiconductor package may include a semiconductor chip 100, a redistribution substrate 200, a molding layer 260, and connection terminals 290.

The semiconductor chip 100 may be disposed on a top surface 200a of the redistribution substrate 200. The semiconductor chip 100 may include a semiconductor substrate 110, chip pads 111, a protection layer 120, a redistribution dielectric layer 130, and redistribution chip pads 131.

The semiconductor substrate 110 may include semiconductor integrated circuits. For example, the semiconductor integrated circuits may constitute a processor, such as a microelectromechanical system (MEMS) device, an optoelectronic device, a central processing unit (CPU), a graphic processing unit (GPU), a mobile application, or a digital signal processor (DSP). For another example, the semiconductor integrated circuits integrated on the semiconductor substrate 110 may constitute a memory device, such as dynamic random access memory (DRAM), static random access memory (SRAM), NAND Flash memory, or resistive random access memory (RRAM).

The chip pads 111 may be disposed on a bottom surface of the semiconductor substrate 110 and electrically connected to the semiconductor integrated circuits.

The protection layer 120 may cover the bottom surface of the semiconductor substrate 110. The protection layer 120 may be formed of a dielectric material, such as silicon oxide or silicon nitride. The protection layer 120 may include, for example, silicon nitride (SiN), silicon oxynitride (SiON), silicon carbonitride (SiCN), high density plasma (HDP) oxide, tetraethylorthosilicate (TEOS), plasma enhanced tetraethylorthosilicate (PETEOS), O₃-tetratthylorthosilicate (O₃-TEOS), undoped silicate glass (USG), phosphosilicate glass (PSG), borosilicate glass (BSG), borophosphosilicate glass (BPSG), fluorosilicate glass (FSG), spin on glass (SOG), tonensilazene (TOSZ), or any combination thereof.

The redistribution dielectric layer 130 may cover the protection layer 120. The redistribution dielectric layer 130 may include a photosensitive polymer. The redistribution dielectric layer 130 may include, for example, at least one selected from photosensitive polyimide, polybenzoxazole, phenolic polymers, and benzocyclobutene polymers.

The redistribution dielectric layer 130 may have a bottom in contact with the protection layer 120, and may also have a top surface that is opposite to the bottom surface and is in contact with the redistribution substrate 200. The redistribution dielectric layer 130 may have a thickness TH ranging from about 2.0 μm to about 4.0 μm.

The redistribution chip pads 131 may penetrate the redistribution dielectric layer 130 and the protection layer 120 and may connect with the chip pads 111. The redistribution chip pads 131 may have top surfaces substantially coplanar with that of the redistribution dielectric layer 130.

The redistribution chip pads 131 may be formed of, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), or an alloy thereof.

Referring to FIG. 2A, each of the redistribution chip pads 131 may include a first barrier metal pattern 131a and a first metal pattern 131b.

The first barrier metal pattern 131a may be disposed between the first metal pattern 131b and the redistribution dielectric layer 130, and may limit and/or prevent a metallic material of the first metal pattern 131b from diffusing toward the redistribution dielectric layer 130. The first barrier metal pattern 131a may have a uniform thickness to cover a sidewall and a bottom surface of the first metal pattern 131b. The top surface of the first barrier metal pattern 131a may be substantially coplanar with that of the first metal pattern 131b and that of the redistribution dielectric layer 130.

Each of the redistribution chip pads 131 may include a via part that penetrates the protection layer 120 and a pad part that is in the redistribution dielectric layer 130. The pad part may have a width greater than that of the via part.

Each of the redistribution chip pads 131 may have an inclined first sidewall SW1. The redistribution chip pads 131 may have a width that increases with increasing distance from the semiconductor substrate 110. Each of the redistribution chip pads 131 may have a first maximum width W1 at the top surface thereof. The first maximum width W1 of the redistribution chip pad 131 may range from about 3.020 μm to about 10.070 μm.

The redistribution chip pads 131 may be disposed spaced apart from each other at a first interval S1, and the first interval S1 may be less than the first maximum width W1 of the redistribution chip pad 131. The first interval S1 may range from about 50 μm to about 130 μm. Alternatively, the first interval S1 may be substantially the same as or greater than the first maximum width W1 of the redistribution chip pad 131.

The redistribution substrate 200 may have a top surface 200a adjacent to the semiconductor chip 100 and a bottom surface 200b opposite to the top surface 200a. The redistribution substrate 200 may include lower coupling pads 211 provided on the bottom surface 200b thereof, upper coupling pads 251 provided on the top surface 200a thereof, and redistribution patterns 221, 231, and 241 the connect the lower coupling pads 211 to the upper coupling pads 251. The redistribution patterns 221, 231, and 241 may be provided in base dielectric layers 210, 220, 230, and 240 that are sequentially stacked.

For example, the redistribution substrate 200 may include first to fourth base dielectric layers 210, 220, 230, and 240 that are sequentially stacked and first to third redistribution patterns 221, 231, and 241 that are sequentially stacked. No limitation is imposed on the number of stacked base dielectric layers included in the redistribution substrate 200, and the number of stacked base dielectric layers may be changed based on a type of the semiconductor package.

In the first base dielectric layer 210, the first redistribution pattern 221 may be coupled to the lower coupling pads 211. Each of the first, second, and third redistribution patterns 221, 231, and 241 may include a via part that penetrates a corresponding one of the first, second, and third base dielectric layers 210, 220, and 230, and may also include a pad part connected to the via part on the corresponding one of the first, second, and third base dielectric layers 210, 220, and 230.

Referring to FIG. 2A, each of the first, second, and third redistribution patterns 221, 231, and 241 may have a flat sidewall that is substantially perpendicular to a top surface of a corresponding one of the first, second, and third base dielectric layers 210, 220, and 230. Each of the first, second, and third redistribution patterns 221, 231, and 241 may include a barrier metal pattern and a metal pattern. Each of the first, second, and third redistribution patterns 221, 231, and 241 may be configured such that a sidewall of the metal pattern may be in direction contact with a corresponding one of the first, second, third, and fourth base dielectric layers 210, 220, 230, and 240.

The upper coupling pads 251 may be disposed in the fourth base dielectric layer 240 and may be connected to the third redistribution patterns 241.

The upper coupling pads 251 may each include a via part that penetrate a portion of the fourth base dielectric layer 240 and a pad part connected to the via part in the fourth base dielectric layer 240.

The upper coupling pads 251 may have top surfaces substantially coplanar with that of the fourth base dielectric layer 240. The top surfaces of the upper coupling pads 251 and the top surface of the fourth base dielectric layer 240 may correspond to the top surface 200a of the redistribution substrate 200.

The pad part of each of the upper coupling pads 251 may have an inclined second sidewall SW2. The upper coupling pads 251 may have a width that increases with increasing distance from the bottom surface 200b of the redistribution substrate 200. Each of the upper coupling pads 251 may have a second maximum width W2 at the top surface thereof. For example, the second maximum width W2 of the upper coupling pad 251 may be substantially the same as the first maximum width W1 of the redistribution chip pad 131. The second maximum width W2 of the upper coupling pad 251 may range from about 20 μm to about 70 μm.

The upper coupling pads 251 may be disposed spaced apart from each other at a second interval S2, and the second interval S2 may be less than the second maximum width W2 of the upper coupling pad 251. The second interval S2 may range from about 50 μm to about 130 μm.

Referring again to FIG. 2A, each of the upper coupling pads 251 may include a second barrier metal pattern 251a and a second metal pattern 251b.

The second barrier metal pattern 251a may be disposed between the second metal pattern 251b and the fourth base dielectric layer 240, and may limit and/or prevent a metallic material of the second metal pattern 251b from diffusing toward the fourth base dielectric layer 240. The second barrier metal pattern 251a may cover a sidewall and a bottom surface of the second metal pattern 251b. The second barrier metal pattern 251a may have a top surface substantially coplanar with that of the second metal pattern 251b and that of the fourth base dielectric layer 240.

The second barrier metal pattern 251a may include the same material as that of the first barrier metal pattern 231a of the redistribution chip pad 131. The second metal pattern 251b may include the same material as that of the first metal pattern 131b of the redistribution chip pad 131.

The second barrier metal pattern 251a of the upper coupling pad 251 may be a double layer or a mixture layer other than the double layer, and may include titanium, titanium nitride, tantalum, tantalum nitride, ruthenium, cobalt, manganese, tungsten nitride, nickel, nickel boride, or titanium/titanium nitride.

The second metal pattern 251b of the upper coupling pad 251 may have a multi-layered structure that includes metal selected from copper (Cu), nickel (Ni), gold (Au), or any alloy thereof, or includes a plurality of metals selected from copper (Cu), nickel (Ni), and gold (Au).

The redistribution substrate 200 may be provided with connection terminals 290 attached to the lower coupling pads 211 thereof. The connection terminals 290 may be solder balls formed of one or more of tin, lead, and copper.

The redistribution substrate 200 may be provided thereon with the molding layer 260 that covers a sidewall of the semiconductor chip 100. The molding layer 260 may include a dielectric polymer, such as an epoxy molding compound (EMC). The molding layer 260 may have a top surface coplanar with that of the semiconductor chip 100. The molding layer 260 may have a bottom surface in direct contact with the top surface 200a of the redistribution substrate 200. The molding layer 260 may have a sidewall vertically aligned with that of the redistribution substrate 200. For example, the sidewall of the molding layer 260 may be coplanar with that of the redistribution substrate 200.

According to some embodiments, a hybrid bonding may be established between a bottom surface of the semiconductor chip 100 and the top surface 200a of the redistribution substrate 200. In this description, the term “hybrid bonding” may denote that two components of the same kind are merged at an interface therebetween.

The upper coupling pads 251 may be coupled to the redistribution chip pads 131 of the semiconductor chip 100, and the fourth base dielectric layer 240 may be coupled to the redistribution dielectric layer 130 of the semiconductor chip 100. For example, the upper coupling pads 251 may be in direct contact with the redistribution chip pads 131, and the top surface of the fourth base dielectric layer 240 may be in direct contact with that of the redistribution dielectric layer 130.

The hybrid bonding may produce an interface IF1 between the fourth base dielectric layer 240 and the redistribution dielectric layer 130, and an interface IF2 may be absent between the upper coupling pads 251 and the redistribution chip pads 131. For example, the hybrid bonding may allow the upper coupling pads 251 and the redistribution chip pads 131 to constitute a unitary single body. The interface IF2 may not be visually observed between the upper coupling pads 251 and the redistribution chip pads 131.

According to the embodiment shown in FIG. 2B, a hybrid bonding may be established between the bottom surface of the semiconductor chip 100 and the top surface 200a of the redistribution substrate 200, and a discontinuous interface IF3 may be formed at a bonding surface between the fourth base dielectric layer 240 of the redistribution substrate 200 and the redistribution dielectric layer 130 of the semiconductor chip 100. For example, an impurity may be interposed or a void IF3 may be formed between the fourth base dielectric layer 240 of the redistribution substrate 200 and the redistribution dielectric layer 130 of the semiconductor chip 100. The impurity or the void IF3 may be generated during the hybrid bonding process.

Referring to FIG. 2C, the upper coupling pads 251 of the redistribution substrate 200 may be directly coupled to the redistribution chip pads 131 of the semiconductor chip 100, and a portion of each upper coupling pad 251 may be in direct contact with the redistribution dielectric layer 130 of the semiconductor chip 100 and a portion of each redistribution chip pad 131 may be in direct contact with the fourth base dielectric layer 240 of the redistribution substrate 200.

referring to FIG. 2D, each of the redistribution chip pads 131 of the semiconductor chip 100 may have a first maximum width W1 at the top surface thereof, and each of the upper coupling pads 251 of the redistribution substrate 200 may have at its top surface a second maximum width W2 greater than the first maximum width W1.

For example, the top surface of the redistribution chip pad 131 may be in full contact with the top surface of the upper coupling pad 251, and a portion of the upper coupling pad 251 may be in contact with the redistribution dielectric layer 130.

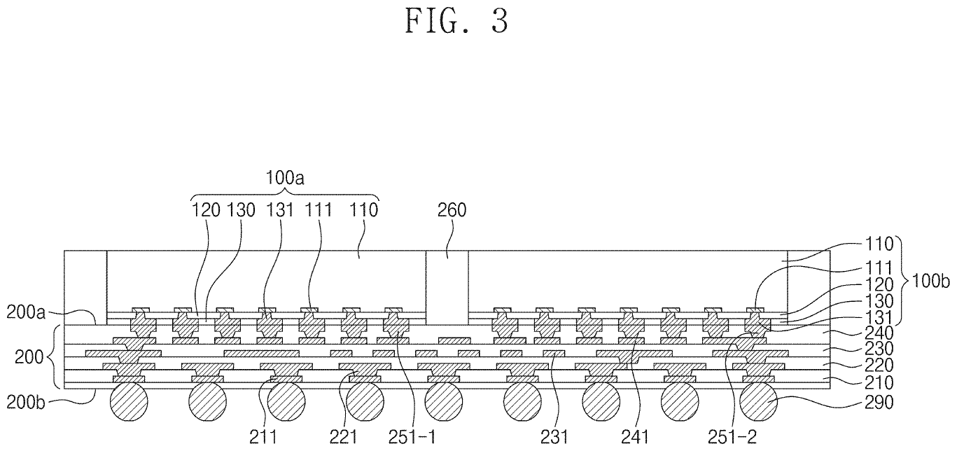

FIGS. 3 to 7 illustrate cross-sectional views showing a semiconductor package according to some embodiments of inventive concepts. The same technical features as those of the embodiments discussed above may be omitted in the interest of brevity of description.

According to the embodiment shown in FIG. 3, a semiconductor package may include first and second semiconductor chips 100a and 100b, a redistribution substrate 200, a molding layer 260, and connection terminals 290.

The first and second semiconductor chips 100a and 100b may be placed on a top surface of the redistribution substrate 200. Likewise, the semiconductor chip 100 discussed above, each of the first and second semiconductor chips 100a and 100b may include a semiconductor substrate 110, chip pads 111, a protection layer 120, a redistribution dielectric layer 130, and redistribution chip pads 131.

The redistribution substrate 200 may include, on its top surface, first upper coupling pads 251-1 and second upper coupling pads 251-2. Likewise, the upper coupling pads 251, the first and second upper coupling pads 251-1 and 251-2 may have top surfaces coplanar with that of the fourth base dielectric layer 240.

A hybrid bonding may be established between the redistribution substrate 200 and each of the first and second semiconductor chips 100a and 100b. For example, the redistribution chip pads 131 of the first semiconductor chip 100a may be coupled to the first upper coupling pads 251-1 of the redistribution substrate 200, and the redistribution chip pads 131 of the second semiconductor chip 100b may be coupled to the second upper coupling pads 251-2 of the redistribution substrate 200.

The top surface of the fourth base dielectric layer 240 in the redistribution substrate 200 may be in direct contact with the redistribution dielectric layers 130 of the first and second semiconductor chips 100a and 100b.

The redistribution substrate 200 may be provided thereon with the molding layer 260 that covers the first and second semiconductor chips 100a and 100b and has a sidewall substantially coplanar with that of the redistribution substrate 200.

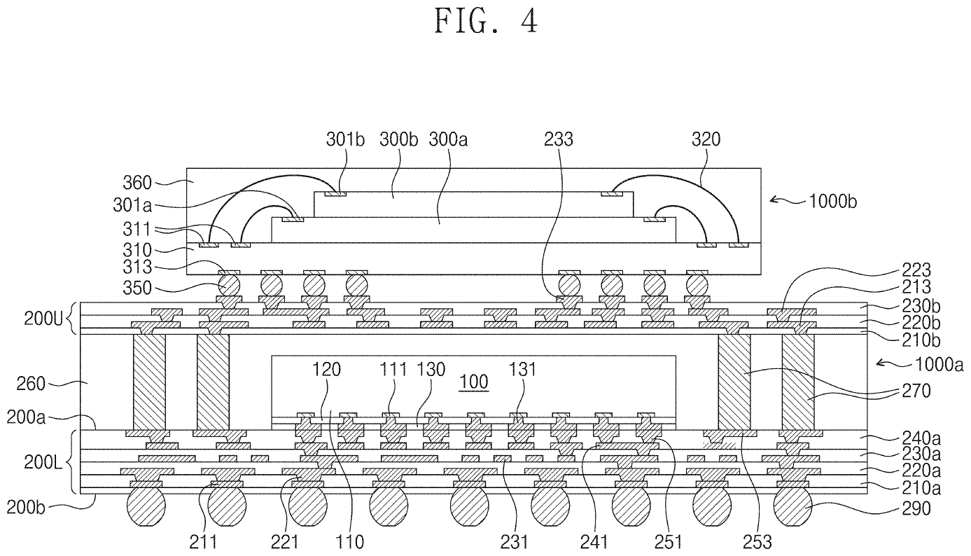

According to the embodiment shown in FIG. 4, a semiconductor package may include a first semiconductor package 1000a and a second semiconductor package 1000b disposed on the first semiconductor package 1000a.

The first semiconductor package 1000a may include a lower redistribution substrate 200L, an upper redistribution substrate 200U, a first semiconductor chip 100, metal pillars 270, and a molding layer 260.

As discussed above, the lower redistribution substrate 200L may include a plurality of base dielectric layers 210a, 220a, 230a, and 240a and a plurality of redistribution patterns 221, 231, and 241, and the upper redistribution substrate 200U may include a plurality of base dielectric layers 210b, 220b, and 230b and a plurality of redistribution patterns 213 and 223.

The first semiconductor chip 100 may be provided on the lower redistribution substrate 200L. When viewed in plan, the first semiconductor chip 100 may be disposed on a central region of the lower redistribution substrate 200L. Like the semiconductor chip 100 discussed above, the first semiconductor chip 100 may include a semiconductor substrate 110, chip pads 111, a protection layer 120, a redistribution dielectric layer 130, and redistribution chip pads 131.

A hybrid bonding may be established between the first semiconductor chip 100 and the lower redistribution substrate 200L. The redistribution chip pads 131 of the first semiconductor chip 100 may be in direct contact with upper coupling pads 251 of the lower redistribution substrate 200L. The redistribution chip pads 131 of the first semiconductor chip 100 may be coupled to the upper coupling pads 251 of the lower redistribution substrate 200L.

The metal pillars 270 may be disposed around the first semiconductor chip 100, and may electrically connect the lower redistribution substrate 200L to the upper redistribution substrate 200U. The metal pillars 270 may penetrate the molding layer 260, and may have top surfaces coplanar with that of the molding layer 260. The metal pillars 270 may have bottom surfaces in direct contact with the upper coupling pads 251 of the lower redistribution substrate 200L.

The molding layer 260 may be provided between the lower and upper redistribution substrates 200L and 200U, and may cover the first semiconductor chip 100. The molding layer 260 may be provided on a top surface of the lower redistribution substrate 200L, and may cover a sidewall and a top surface of the first semiconductor chip 100. The molding layer 260 may fill gaps between the metal pillars 270, and may have a thickness substantially the same as a length of each of the metal pillars 270. The molding layer 260 may include a dielectric polymer, such as an epoxy-based molding compound.

The lower redistribution substrate 200L may be provided with first connection terminals 290 attached to lower coupling pads 211 thereof. The first connection terminals 290 may be solder balls formed of one or more of tin, lead, and copper.

The second semiconductor package 1000b may be disposed on the upper redistribution substrate 200U. Like the lower redistribution substrate 200L, the upper redistribution substrate 200U may include base dielectric layers 210b, 220b, and 230b, redistribution patterns 213 and 223, and upper coupling pads 233.

The second semiconductor package 1000b may include a package substrate 310, a second semiconductor chip 300a, a third semiconductor chip 300b, and an upper molding layer 360.

The package substrate 310 may be a printed circuit board. Alternatively, the redistribution substrate 200 may be used as the package substrate 310. One or more lower conductive pads 313 may be disposed on a bottom surface of the package substrate 310.

The second and third semiconductor chips 300a and 300b may be disposed on the package substrate 310. The second and third semiconductor chips 300a and 300b may include integrated circuits, and the integrated circuits may include a memory circuit, a logic circuit, or a combination thereof.

The second and third semiconductor chips 300a and 300b may each be a semiconductor chip whose function is different from that of the first semiconductor chip 100. For example, when the first semiconductor chip 100 is a logic chip, the second and third semiconductor chips 300a and 300b may be memory chips, or vice versa. Alternatively, the second and third semiconductor chips 300a and 300b may each be a semiconductor chip whose function is the same as that of the first semiconductor chip 100.

The second and third semiconductor chips 300a and 300b may have their chip pads 301a and 301b each of which is electrically connected through a bonding wire 320 to an upper conductive pad 311 on a top surface of the package substrate 310. The upper conductive pad 311 may be electrically connected to a lower conductive pad 313 through an internal line within the package substrate 310.

The upper molding layer 360 may be provided on the package substrate 310 to cover the second and third semiconductor chips 300a and 300b. The upper molding layer 360 may include a dielectric polymer, such as an epoxy-based polymer.

A plurality of second connection terminals 350 may connect the lower conductive pads 313 of the package substrate 310 to the upper coupling pads 233 of the upper redistribution substrate 200U. The second connection terminals 350 may be solder balls formed of one or more of tin, lead, and copper.

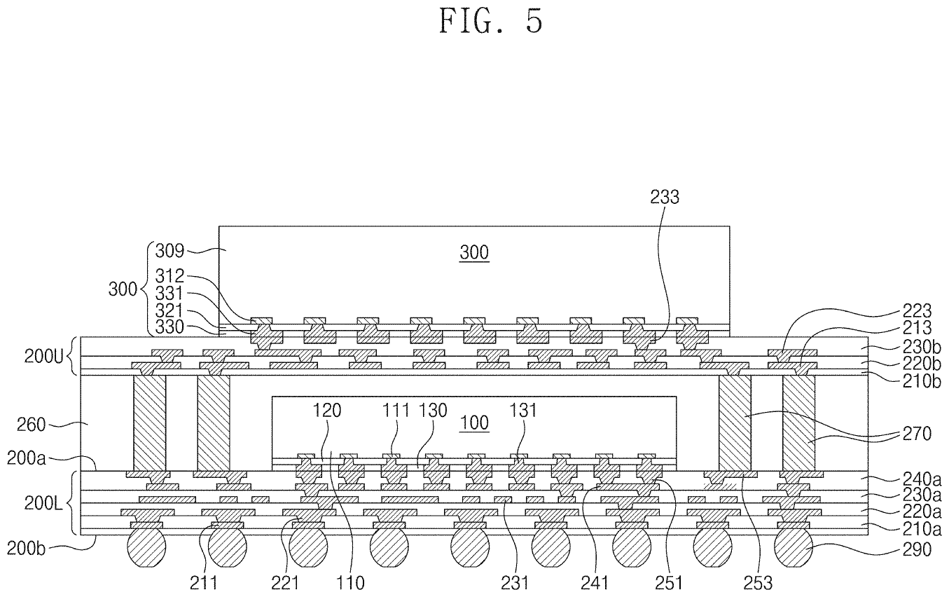

According to the embodiment shown in FIG. 5, a semiconductor package may include a lower redistribution substrate 200L, an upper redistribution substrate 200U, a first semiconductor chip 100, metal pillars 270, a molding layer 260, and a second semiconductor chip 300. The lower redistribution substrate 200L, the upper redistribution substrate 200U, the first semiconductor chip 100, the metal pillars 270, and the molding layer 260 may be substantially the same as those of the first semiconductor package 1000a discussed with reference to FIG. 4.

According to the present embodiment, like the first semiconductor chip 100, the second semiconductor chip 300 may include a semiconductor substrate 309, chip pads 312, a protection layer 321, a redistribution dielectric layer 330, and redistribution chip pads 331.

Like the lower redistribution substrate 200L, the upper redistribution substrate 200U may be configured such that upper coupling pads 233 may have top surfaces substantially coplanar with that of a base dielectric layer 230b.

The redistribution dielectric layer 330 of the second semiconductor chip 300 may be in direct contact with the base dielectric layer 230b of the upper redistribution substrate 200U, and the redistribution chip pads 331 of the second semiconductor chip 300 may be in direct contact with the upper coupling pads 233 of the upper redistribution substrate 200U. The redistribution chip pads 331 of the second semiconductor chip 300 may correspond to the upper coupling pads 233 of the upper redistribution substrate 200U, and may have their size and arrangement substantially the same as those of the upper coupling pads 233 of the upper redistribution substrate 200U.

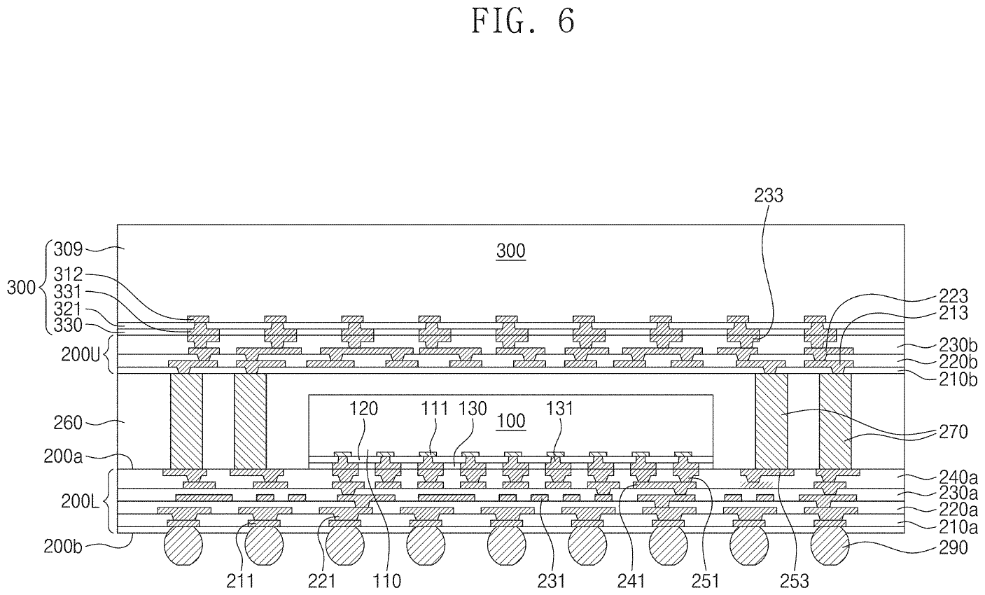

According to the embodiment shown in FIG. 6, a semiconductor package may include a lower redistribution substrate 200L, an upper redistribution substrate 200U, a first semiconductor chip 100, metal pillars 270, a molding layer 260, and a second semiconductor chip 300. The semiconductor package according to the present embodiment may be substantially the same as the semiconductor package discussed with reference to FIG. 5.

According to the present embodiment, like the first semiconductor chip 100, the second semiconductor chip 300 may include a semiconductor substrate 309, chip pads 312, a protection layer 321, a redistribution dielectric layer 330, and redistribution chip pads 331.

When viewed in plan, the second semiconductor chip 300 may overlap the metal pillars 270 and the first semiconductor chip 100. The second semiconductor chip 300 may have a width substantially the same as that of the molding layer 260. For example, a lateral surface of the second semiconductor chip 300 may be vertically aligned and substantially coplanar with that of the molding layer 260.

The redistribution dielectric layer 330 of the second semiconductor chip 300 may be in direct contact with the base dielectric layer 230b of the upper redistribution substrate 200U, and the redistribution chip pads 331 of the second semiconductor chip 300 may be in direct contact with the upper coupling pads 233 of the upper redistribution substrate 200U.

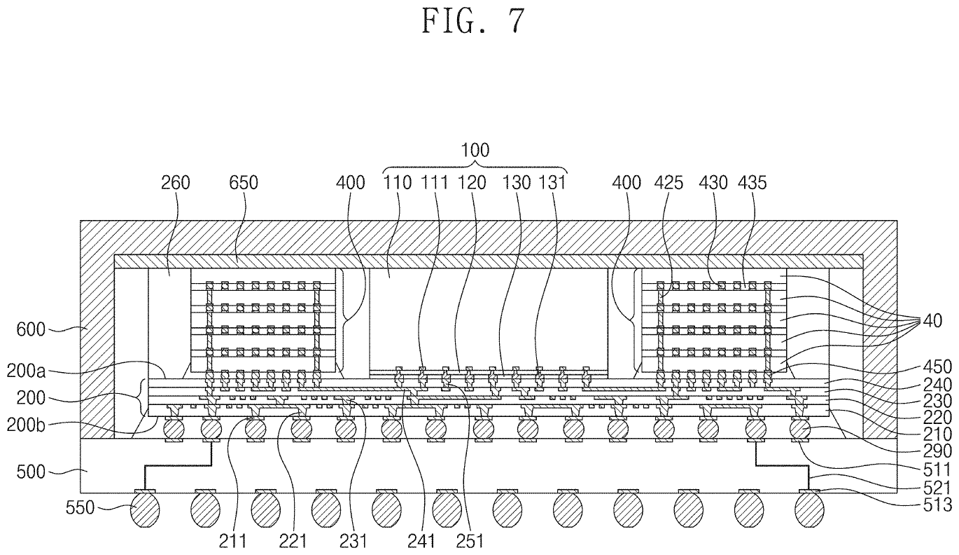

According to the embodiment shown in FIG. 7, a semiconductor package may include a semiconductor chip 100, semiconductor chip stacks 400, a redistribution substrate 200, a package substrate 500, and a thermal radiation structure 600.

The semiconductor chip 100 and the semiconductor chip stacks 400 may be disposed on a top surface of the redistribution substrate 200. Like the semiconductor chip 100 discussed above, the semiconductor chip 100 may include a semiconductor substrate 110, chip pads 111, a protection layer 120, a redistribution dielectric layer 130, and redistribution chip pads 131.

The semiconductor chip 100 may be a logic chip including a processor, such as microelectromechanical system (MEMS) device, optoelectronic device, central processing unit (CPU), graphic processing unit (GPU), mobile application, or digital signal processor (DSP).

A hybrid bonding may be established between the semiconductor chip 100 and the redistribution substrate 200. The redistribution chip pads 131 of the semiconductor chip 100 may be in direct contact with upper coupling pads 251 of the redistribution substrate 200. The redistribution chip pads 131 of the semiconductor chip 100 may be direct coupled to the upper coupling pads 251 of the redistribution substrate 200.

The semiconductor chip stacks 400 may be disposed on the redistribution substrate 200 while being spaced apart from the semiconductor chip 100. Each of the semiconductor chip stacks 400 may include a plurality of memory chips 40 that are vertically stacked. The plurality of memory chips 40 may be electrically connected to each other through upper and lower chip pads, chip through vias 425, and connection bumps 430. The memory chips 40 may be stacked on the redistribution substrate 200 to achieve alignment of their sidewalls. An adhesion layer 435 may be provided between the memory chips 40. The adhesion layer 435 may be, for example, a polymer tape including a dielectric material. The adhesion layer 435 may be interposed between the connection bumps 430, and thus an electrical short may be limited and/or prevented between the connection bumps 430.

The semiconductor chip stacks 400 may be connected through first connection terminals 450 to the redistribution substrate 200. The first connection terminals 450 may be attached to chip pads of the semiconductor chip stacks 400. The first connection terminals 450 may be one or more of solder balls, conductive bumps, and conductive pillars. The first connection terminals 450 may include at least one selected from copper, tin, and lead. The first connection terminals 450 may each have a thickness of, for example, about 30 μm to about 70 μm. In some embodiments, it is explained that the semiconductor chip stacks 400 are connected through the first connection terminals 450 to the redistribution substrate 200, but inventive concepts are not limited thereto, and like the semiconductor chip 100 discussed above, a hybrid bonding may be established to achieve connection between the redistribution substrate 200 and the semiconductor chip stacks 400.

The redistribution substrate 200 may be provided thereon with a molding layer 260 that covers the semiconductor chip 100 and the semiconductor chip stacks 400. The molding layer 260 may have a sidewall aligned with that of the redistribution substrate 200. The molding layer 260 may have a top surface substantially coplanar with that of the semiconductor chip 100 and those of the semiconductor chip stacks 400. The molding layer 260 may include a dielectric polymer, such as an epoxy molding compound (EMC).

A first under-fill layer may be interposed between the redistribution substrate 200 and the semiconductor chip stacks 400. The first under-fill layer may fill gaps between the first connection terminals 450. The first under-fill layer may include, for example, a thermo-curable resin or a photo-curable resin. The first under-fill layer may further include inorganic fillers or organic fillers. In some embodiments, the first under-fill layer may be omitted, and instead the molding layer 260 may fill gaps between the redistribution substrate 200 and bottom surfaces of the semiconductor chip stacks 400.

The redistribution substrate 200 may be disposed on the package substrate 500, and may be connected through second connection terminals 290 to the package substrate 500. The redistribution substrate 200 may include a chip region and an edge region around the chip region. The semiconductor chip 100 and the semiconductor chip stacks 400 may be disposed on the chip region of the redistribution substrate 200.

The second connection terminals 290 may be attached to lower coupling pads 211 of the redistribution substrate 200. The second connection terminals 290 may be solder balls formed of one or more of tin, lead, and copper. The second connection terminals 290 may each have a thickness of about 40 μm to about 80 μm.

The package substrate 500 may be, for example, a printed circuit board, a flexible substrate, or a tape substrate. For example, the package substrate 500 may be one of a flexible printed circuit board, a rigid printed circuit board, and any combination thereof, each of which boards includes internal lines 521 formed therein.

The package substrate 500 may have a top surface and a bottom surface that are opposite to each other, and may include upper conductive pads 511, lower conductive pads 513, and internal lines 521. The upper conductive pads 511 may be arranged on the top surface of the package substrate 500, and the lower conductive pads 513 may be arranged on the bottom surface of the package substrate 500. The upper conductive pads 511 may be electrically connected through the internal lines 521 to the lower conductive pads 513. A plurality of external coupling terminals 550 may be attached to the lower conductive pads 513. A ball grid array (BGA) may be provided as the external coupling terminals 550.

The thermal radiation structure 600 may include a thermal conductive material. The thermal conductive material may include a metallic material (e.g., copper and/or aluminum) or a carbon-containing material (e.g., graphene, graphite, and/or carbon nano-tube). The thermal radiation structure 600 may have a relatively high thermal conductivity. For example, a single metal layer or a plurality of stacked metal layers may be used as the thermal radiation structure 600. For another example, the thermal radiation structure 600 may include a heat sink or a heat pipe. For another example, the thermal radiation structure 600 may be configured to use water cooling.

A thermal conductive layer 650 may be interposed between the thermal radiation structure 600 and the semiconductor chip 100 and between the thermal radiation structure 600 and the semiconductor chip stacks 400. The thermal conductive layer 650 may be in contact with a top surface of the semiconductor package and a bottom surface of the thermal radiation structure 600. The thermal conductive layer 650 may include a thermal interface material (TIM). The thermal interface material may include, for example, a polymer and thermal conductive particles. The thermal conductive particles may be dispersed in the polymer. When the semiconductor package operates, heat produced from the semiconductor package may be transferred through the thermal conductive layer 650 to the thermal radiation structure 600.

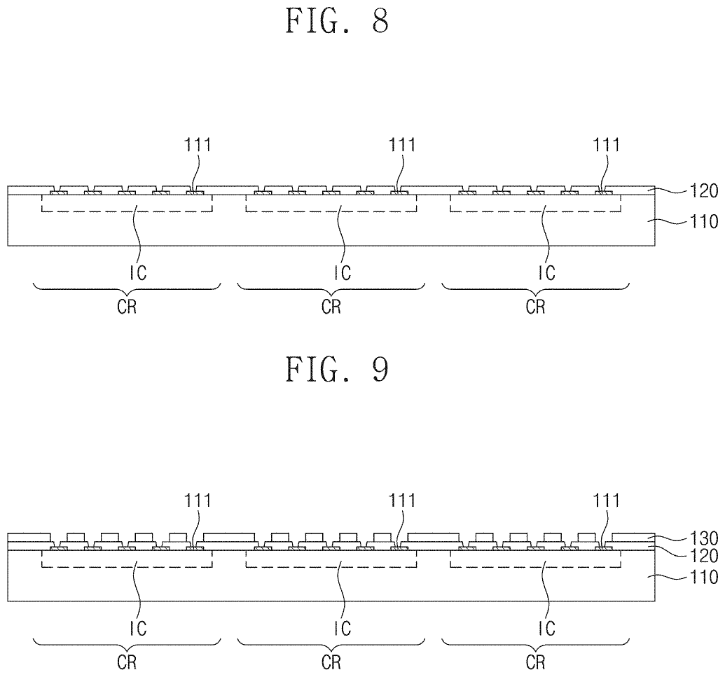

FIGS. 8 to 18 illustrate cross-sectional views showing a method of fabricating a semiconductor package according to some embodiments of inventive concepts.

Referring to FIG. 8, a semiconductor substrate 110 may include chip regions CR on which semiconductor integrated circuits IC are formed, and may also include a scribe line region between the chip regions CR. The chip regions CR may be two-dimensionally arranged along rows and columns.

The semiconductor substrate 110 may be, for example, a silicon substrate, a germanium substrate, a silicon-on-insulator (SOI) substrate, or a germanium-on-insulator (GOI) substrate. For example, the semiconductor substrate 110 may be a silicon wafer.

The semiconductor integrated circuits IC may include a semiconductor memory device, such as dynamic random access memory (DRAM), static random access memory (SRAM), NAND Flash memory, or resistive random access memory (RRAM). Alternatively, the semiconductor integrated circuits IC may include a processor, such as microelectromechanical system (MEMS) device, optoelectronic device, central processing unit (CPU), graphic processing unit (GPU), mobile application, or digital signal processor (DSP).

A plurality of chip pads 111 may be formed on a first surface of the semiconductor substrate 110. On each chip region CR, the chip pads 111 may be electrically connected to the semiconductor integrated circuits IC.

On the first surface of the semiconductor substrate 110, a protection layer 120 may be formed which has openings that expose the chip pads 111. The protection layer 120 may include silicon oxide. The protection layer 120 may be formed of, for example, silicon nitride (SiN), silicon oxynitride (SiON), silicon carbonitride (SiCN), high density plasma (HDP) oxide, tetraethylorthosilicate (TEOS), plasma enhanced tetraethylorthosilicate (PETEOS), O₃-tetratthylorthosilicate (O₃-TEOS), undoped silicate glass (USG), phosphosilicate glass (PSG), borosilicate glass (BSG), borophosphosilicate glass (BPSG), fluorosilicate glass (FSG), spin on glass (SOG), tonensilazene (TOSZ), or any combination thereof.

Referring to FIG. 9, on the protection layer 120, a redistribution dielectric layer 130 may be formed which has openings that expose the chip pads 111.

The redistribution dielectric layer 130 may include a photosensitive dielectric material. The redistribution dielectric layer 130 may include, for example, a polyimide-based material such as photosensitive polyimide (PSPI). For another example, the redistribution dielectric layer 130 may include at least one selected from polybenzoxazole (PBO), phenolic polymers, benzocyclobutene (BCB) polymers, and epoxy-based polymers.

A spin coating process may deposit the redistribution dielectric layer 130 on a dielectric layer, and the redistribution dielectric layer 130 may undergo exposure and development processes to form openings that partially expose the chip pads 111 and the protection layer 120, without separately forming a photoresist layer.

The openings formed in the redistribution dielectric layer 130 may include trenches formed in the redistribution dielectric layer 130 and via holes formed in the protection layer 120. The openings formed in the redistribution dielectric layer 130 may each have an inclined sidewall and a width that decreases in a downward direction. For example, the openings formed in the redistribution dielectric layer 130 may each have a width that increases with increasing distance from the chip pad 111.

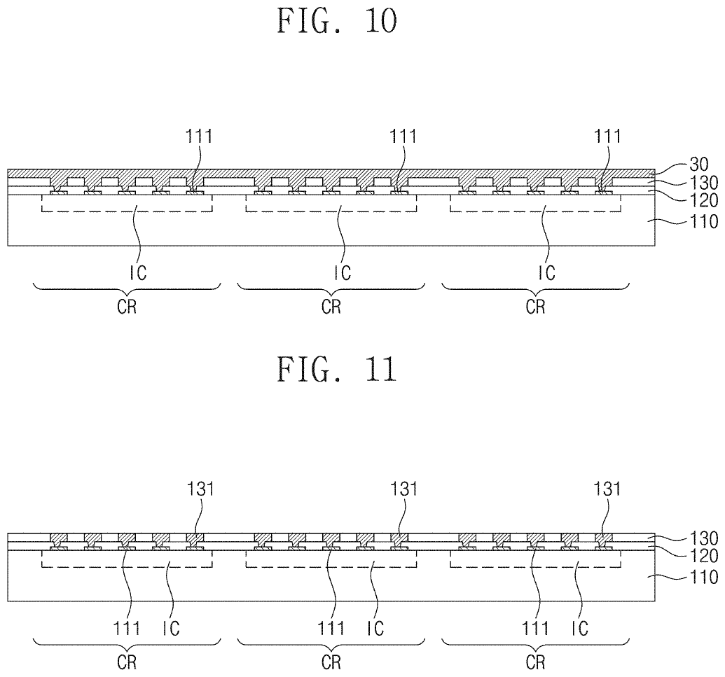

Referring to FIG. 10, a barrier metal layer (not shown), a metal seed layer (not shown), and a metal layer 30 may be sequentially formed on the redistribution dielectric layer 130 in which the openings are formed.

The barrier metal layer and the metal seed layer may be formed by using physical vapor deposition (PVD), chemical vapor deposition (CVD), or atomic layer deposition (ALD). The barrier metal layer may include, for example, a double layer or a mixture layer other than the double layer, and may include titanium, titanium nitride, tantalum, tantalum nitride, ruthenium, cobalt, manganese, tungsten nitride, nickel, nickel boride, or titanium/titanium nitride. The metal seed layer may include, for example, copper (Cu).

The metal layer 30 may be formed by a thin-layer deposition method such as electroplating, electroless plating, or sputtering. The metal layer 30 may include, for example, copper (Cu) or a copper alloy. In this description, the copper alloy may mean copper mixed with an extremely small amount of one of C, Ag, Co, Ta, In, Sn, Zn, Mn, Ti, Mg, Cr, Ge, Sr, Pt, Mg, Al, and Zr.

Referring to FIG. 11, the metal layer 30 may undergo a planarization process to expose a top surface of the redistribution dielectric layer 130. A chemical mechanical polishing (CMP) process may be performed as the planarization process. The planarization process may form redistribution chip pads 131 that are separated from each other. The redistribution chip pads 131 may have top surfaces substantially coplanar with that of the redistribution dielectric layer 130.

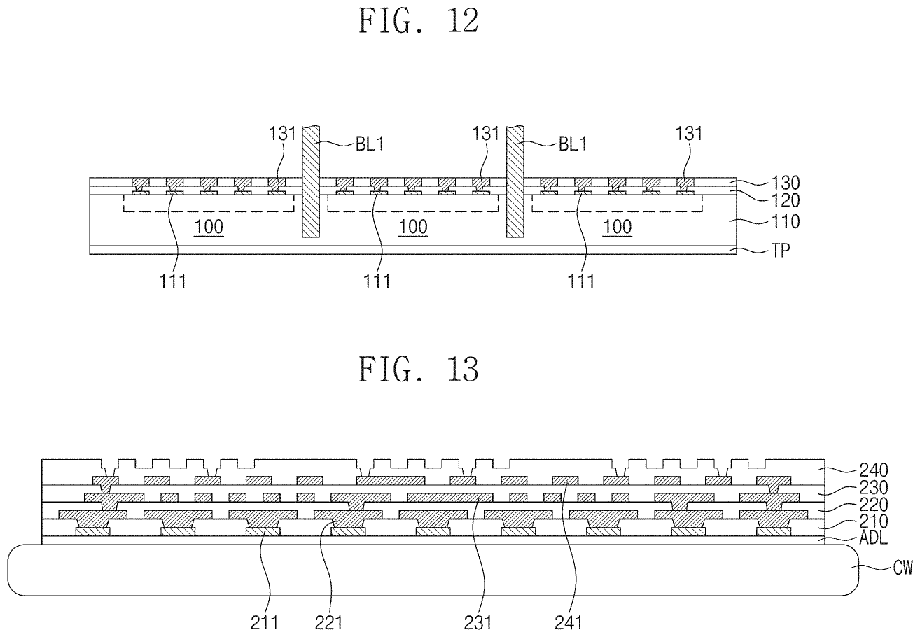

Referring to FIG. 12, a cutting process may be performed in which the semiconductor substrate 110 is cut along the scribe line region. The cutting process may form semiconductor chips 100 individually separated from each other. The cutting process may use a cutting tool BL1 (e.g., a sawing blade and/or a laser). The cutting process may be performed after an adhesion tape TP is attached to a second surface of the semiconductor substrate 110. The adhesion tape TP may have elasticity and may lose adhesiveness by heat or ultraviolet light.

Before the cutting process is performed, an electrical test process may be executed on the semiconductor integrated circuits IC on each chip region CR.

Referring to FIG. 13, a plurality of redistribution layers may be formed on a carrier substrate CW. For example, first to fourth redistribution layers may be sequentially formed on the carrier substrate CW, and an adhesion layer ADL may be interposed between the first redistribution layer and the carrier substrate CW.

The carrier substrate CW may be a glass substrate or a semiconductor substrate. The carrier substrate CW may include chip regions and a scribe line region between the chip regions. The adhesion layer ADL may be, for example, a polymer tape including a dielectric material.

The first redistribution layer may include first redistribution patterns 221 and a first base dielectric layer 210 that covers lower coupling pads 211.

The lower coupling pads 211 may be formed by performing a deposition process, a patterning process, an electroplating process, or an electroless plating process. The lower coupling pads 211 may be formed of, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), carbon (C), or an alloy thereof.

The first base dielectric layer 210 may be formed by a coating process, such as spin coating or slit coating. The first base dielectric layer 210 may include, for example, a photosensitive polymer. The photosensitive polymer may include, for example, at least one selected from photosensitive polyimide, polybenzoxazole, phenolic polymers, and benzocyclobutene polymers. Alternatively, the first base dielectric layer 210 may be formed of, for example, a silicon oxide layer, a silicon nitride layer, or a silicon oxynitride layer.

Each of the first redistribution patterns 221 may include a via part that penetrates the first base dielectric layer 210, and may also include a pad part that is connected to the via part and is disposed on the first base dielectric layer 210.

The formation of the first redistribution patterns 221 may include, for example, forming in the first base dielectric layer 210 a plurality of via holes that expose the lower coupling pads 211, depositing a barrier metal layer and a metal seed layer on the first base dielectric layer 210 in which the first via holes are formed, forming on the metal seed layer a plurality of photoresist patterns having trenches, forming a metal layer than fills the trenches and the first via holes in which the metal seed layer is formed, removing the photoresist patterns, and then etching the barrier metal layer and the metal seed layer.

The first base dielectric layer 210 may be sequentially provided thereon with a second base dielectric layer 220, second redistribution patterns 231 connected to the first redistribution patterns 221, a third base dielectric layer 230, and third redistribution patterns 241 connected to the second redistribution patterns 231.

The second and third base dielectric layers 220 and 230 may include the same material as that of the first base dielectric layer 210, and the formation of the second and third redistribution patterns 231 and 241 may be similar to that of the first redistribution patterns 221.

A fourth base dielectric layer 240 may be formed on the third base dielectric layer 230, covering the third redistribution patterns 241. The fourth base dielectric layer 240 may include, for example, a photosensitive polymer. The photosensitive polymer may include, for example, at least one selected from photosensitive polyimide, polybenzoxazole, phenolic polymers, and benzocyclobutene polymers.

A plurality of openings may be formed on the fourth base dielectric layer 240, exposing portions of the third redistribution patterns 241. The openings of the fourth base dielectric layer 240 may include via holes that penetrate the fourth base dielectric layer 240 and expose the third redistribution patterns 241, and may also include trenches that are spatially connected to the via holes.

The openings of the fourth base dielectric layer 240 may be formed by exposure and development processes performed on the fourth base dielectric layer 240, without separately forming a photoresist layer. The openings formed in the fourth base dielectric layer 240 may each have an inclined sidewall and a width that decreases in a downward direction.

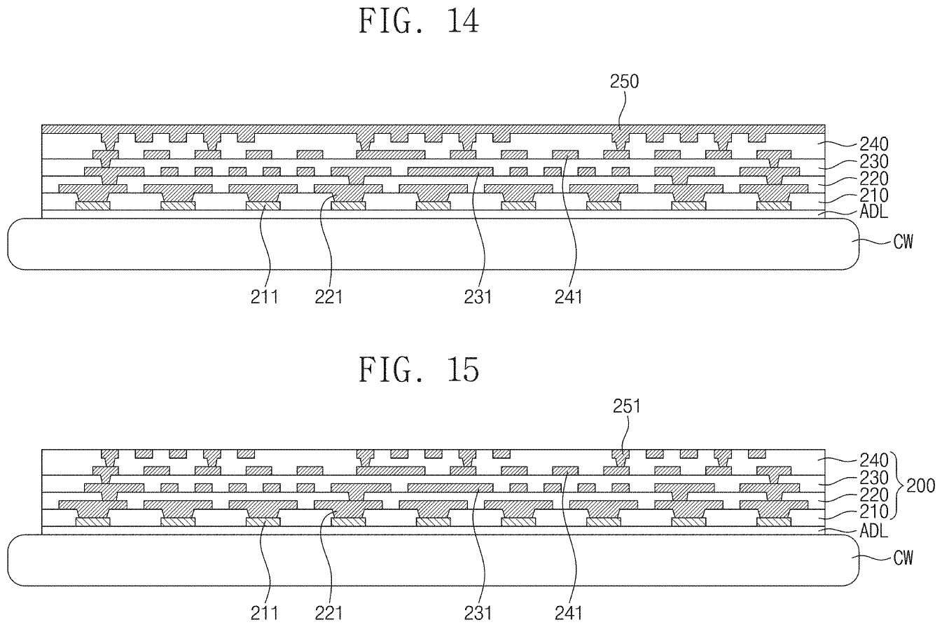

Referring to FIG. 14, a barrier layer (not shown), a metal seed layer (not shown), and a metal layer 250 may be sequentially formed on the fourth base dielectric layer 240 in which the openings are formed. The barrier metal layer and the metal seed layer may each be deposited to have a substantially uniform thickness on the fourth base dielectric layer 240 in which the openings are formed. The barrier metal layer and the metal seed layer may be formed by using physical vapor deposition (PVD), chemical vapor deposition (CVD), or atomic layer deposition (ALD).

The barrier metal layer may include, for example, a double layer or a mixture layer other than the double layer, and may include titanium, titanium nitride, tantalum, tantalum nitride, ruthenium, cobalt, manganese, tungsten nitride, nickel, nickel boride, or titanium/titanium nitride. The metal seed layer may include, for example, copper (Cu).

The metal layer 250 may completely fill the openings in which the metal seed layer is formed. The metal layer 250 may be formed by performing a plating process, such as electroplating, electroless plating, or pulse plating. The metal layer 250 may include, for example, copper (Cu) or a copper alloy. In this description, the copper alloy may mean copper mixed with an extremely small amount of one of C, Ag, Co, Ta, In, Sn, Zn, Mn, Ti, Mg, Cr, Ge, Sr, Pt, Mg, Al, and Zr.

Referring to FIG. 15, the metal layer 250 may undergo a planarization process to expose a top surface of the fourth base dielectric layer 240. A chemical mechanical polishing (CMP) process may be performed as the planarization process. The planarization process may form upper coupling pads 251 in the fourth base dielectric layer 240. Therefore, a redistribution substrate 200 may be manufactured on the carrier substrate CW. The redistribution substrate 200 may include chip regions and a scribe line region between the chip regions.

The planarization process may allow the upper coupling pads 251 to have substantially flat top surfaces. In addition, the top surfaces of the upper coupling pads 251 may be substantially coplanar with that of the fourth base dielectric layer 240.

After the planarization process, a step difference may be present between the top surface of the fourth base dielectric layer 240 and top surfaces of the upper coupling pads 251, and the step difference may have a step height of equal to or less than about 50 nm.

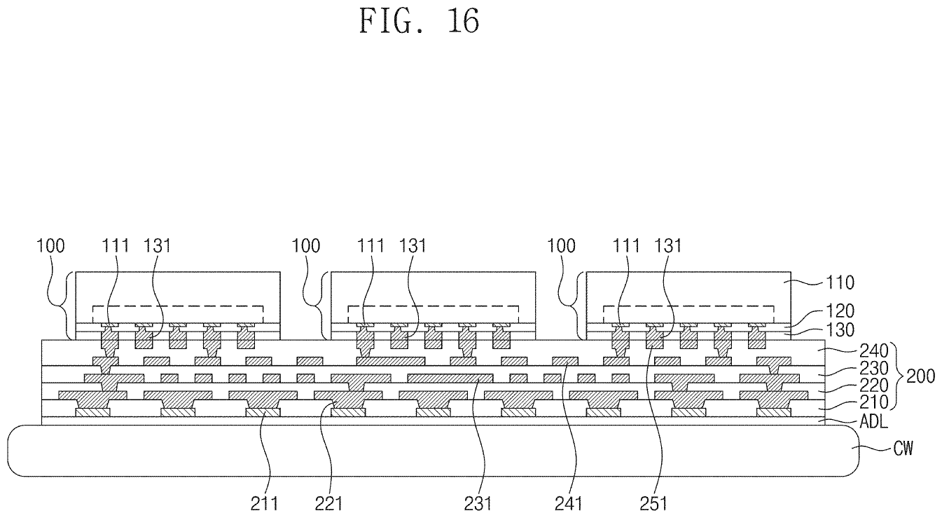

Referring to FIG. 16, semiconductor chips 100 may be provided on corresponding chip regions of the carrier substrate CW, and a hybrid bonding process may be performed to directly connect the redistribution chip pads 131 of the semiconductor chips 100 to the upper coupling pads 251 on the carrier substrate CW.

For example, the semiconductor chips 100 may be positioned on the chip regions of the carrier substrate CW so as to allow the redistribution chip pads 131 of the semiconductor chips 100 to correspond to the upper coupling pads 251 of the fourth base dielectric layer 240, and then a thermocompression process may be performed to couple the semiconductor chips 100 to the redistribution substrate 200.

The thermocompression process may cause copper atoms of the redistribution chip pads 131 and the upper coupling pads 251 to mutually diffuse to eliminate boundaries between the redistribution chip pads 131 and the upper coupling pads 251. In this case, the redistribution chip pad 131 and the upper coupling pad 251 may be formed into a unitary single body.

In addition, the hybrid bonding process may couple the fourth base dielectric layer 240 on the carrier substrate CW to the redistribution dielectric layer 130 of the semiconductor chip 100. In this case, the top surface of the fourth base dielectric layer 240 may be in direct contact with the top surface of the redistribution dielectric layer 130 in the semiconductor chip 100.

For example, the hybrid bonding process may be performed under a pressure of less than about 300 kPa at a temperature of about 250° C. to about 500° C. No limitation is imposed on the aforementioned temperature and pressure when the hybrid bonding process is performed.

Moreover, in the hybrid bonding process, a surface activation process may be performed on surfaces of the redistribution chip pads 131 and surfaces of the upper coupling pads 251. The surface activation process may include plasma treatment or fast atom bombardment (FAB) treatment.

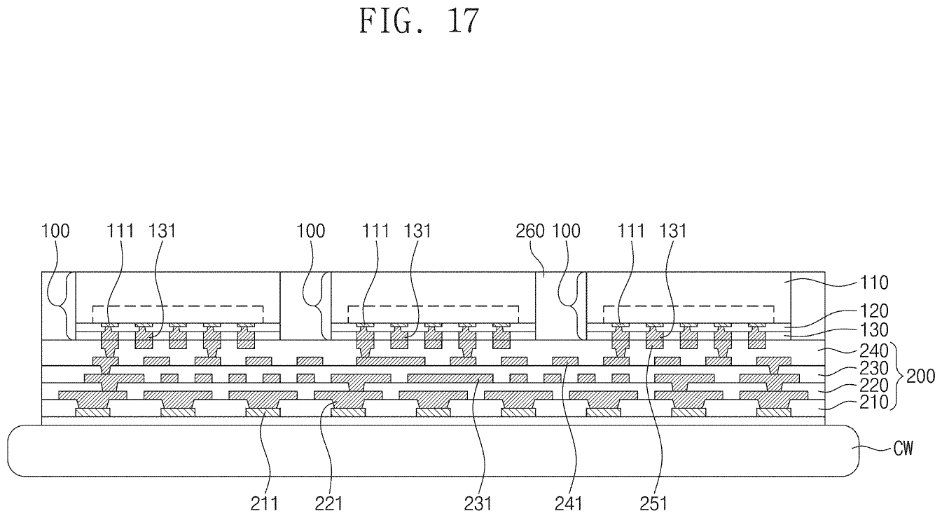

Referring to FIG. 17, a molding layer 260 may be formed on the carrier substrate CW, covering the semiconductor chips 100. The molding layer 260 may be thicker than each of the semiconductor chips 100, and may fill gaps between the semiconductor chips 100. The molding layer 260 may include a dielectric polymer, such as an epoxy molding compound (EMC).

A thinning process may be performed on the molding layer 260, and thus top surfaces of the semiconductor chips 100 may be exposed. The thinning process may include a grinding process, a chemical mechanical polishing process, or an etching process. When a grinding process is performed on the molding layer 260, portions of the semiconductor chips 100 may be removed.

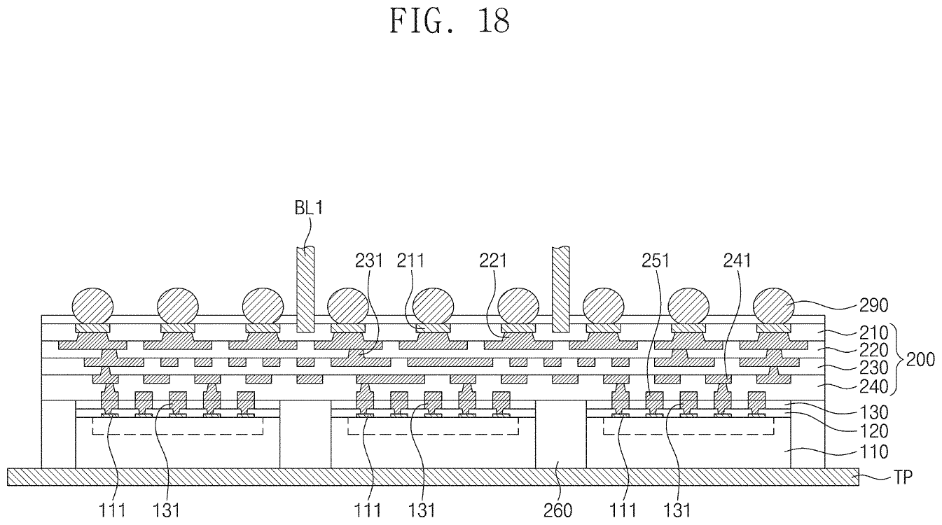

Referring to FIG. 18, after the molding layer 260 is formed, an adhesion tape TP may be attached to the top surfaces of the semiconductor chips 100.

After the adhesion tape TP is attached, the adhesion layer ADL on a bottom surface of the first base dielectric layer 210 may be removed to remove the carrier substrate CW. The removal of the carrier substrate CW may expose the lower coupling pads 211 of the redistribution substrate 200.

A plurality of connection terminals 290 may be attached to the lower coupling pads 211 of the redistribution substrate 200. The connection terminals 290 may be electrically connected through the first, second, and third redistribution patterns 221, 231, and 241 to the upper coupling pads 251 of the redistribution substrate 200. The connection terminals 290 may be solder balls formed of one or more of tin, lead, and copper.

After the formation of the connection terminals 290, a cutting process may be performed such that a cutting tool BL1 may be used to cut the molding layer 260 and the redistribution substrate 200 along the scribe line region of the redistribution substrate 200.

In the cutting process, the chip regions of the redistribution substrate 200 may be individually separated from each other to form semiconductor packages. The cutting process may use a sawing blade or a laser.

According to some embodiments of inventive concepts, a hybrid bonding may be established between redistribution chip pads of a semiconductor chip and upper coupling pads of a redistribution substrate, and thus the redistribution chip pads and the upper coupling pads may be directly connected to each other without bumps.

Because it is possible to omit the bumps that connect the semiconductor chip to the redistribution substrate, semiconductor packages may reduce in pitch between pads and may decrease in thickness. Accordingly, the semiconductor packages may become small in size.

In addition, the reduction in pitch between the pads of the semiconductor packages may limit and/or prevent the occurrence of crack or electrical short between the redistribution chip pads and the upper coupling pads. As a result, it may be possible to increase reliability of electrical connection between the semiconductor chip and the redistribution substrate.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although inventive concepts have been described in connection with some embodiments of inventive concepts illustrated in the accompanying drawings, it will be understood to those skilled in the art that various changes and modifications may be made without departing from the technical spirit and essential feature of inventive concepts. It will be apparent to those skilled in the art that various substitution, modifications, and changes may be thereto without departing from the scope and spirit of inventive concepts.

1. A semiconductor package, comprising:
a redistribution substrate including a base dielectric layer, a plurality of lower coupling pads on a bottom surface of the base dielectric layer, a plurality of upper coupling pads in the base dielectric layer, and a plurality of redistribution patterns that connect the plurality of lower coupling pads and the plurality of upper coupling pads to each other in the base dielectric layer,
top surfaces of the upper coupling pads being coplanar with a top surface of the base dielectric layer;
a semiconductor chip on the redistribution substrate, the semiconductor chip including a semiconductor substrate that includes a plurality of chip pads, a protection layer that covers a top surface of the semiconductor substrate, a redistribution dielectric layer on the protection layer, and a plurality of redistribution chip pads that penetrate the redistribution dielectric layer and the protection layer and are connected to the plurality of chip pads, top surfaces of the plurality of redistribution chip pads being coplanar with a top surface of the redistribution dielectric layer;
a molding layer on a top surface of the redistribution substrate and covering the semiconductor chip; and
a plurality of connection terminals on a bottom surface of the redistribution substrate and connected to the plurality of lower coupling pads,
wherein the top surface of the redistribution dielectric layer is bonded to a top surface of the base dielectric layer, and the plurality of redistribution chip pads are bonded to the plurality of upper coupling pads,
wherein each of the plurality of redistribution chip pads has an inclined first sidewall and a first top surface that has a first maximum width,
wherein each of the plurality of upper coupling pads has an inclined second sidewall and a second top surface that has a second maximum width, the second top surface being directly coupled to the first top surface, and
wherein the first maximum width and the second maximum width have a range of about 20 μm to about 70 μm.

2. The semiconductor package of claim 1, wherein a thickness of the redistribution dielectric layer has a range of about 2.0 μm to about 4.0 μm.

3. The semiconductor package of claim 1, wherein
a width of each of the plurality of redistribution chip pads increases with an increasing distance from the plurality of chip pads, and
a width of each of the plurality of upper coupling pads increases in a direction from a bottom toward top surfaces of the base dielectric layer.

4. The semiconductor package of claim 1, wherein an interval between adjacent ones of the plurality of redistribution chip pads is less than the first maximum width.

5. The semiconductor package of claim 1,
wherein each of the redistribution chip pads includes a first metal pattern and a first barrier metal pattern,
the first metal pattern is in the redistribution dielectric layer, and
the first barrier metal pattern has a uniform thickness and covers a bottom surface of the first metal pattern and a sidewall of the first metal pattern,
wherein each of the upper coupling pads includes a second metal pattern and a second barrier metal pattern,
the second metal pattern is in the base dielectric layer, and
the second barrier metal pattern has a uniform thickness and covers a bottom surface of the second metal pattern and a sidewall of the second metal pattern,
wherein the first barrier metal pattern is in direct contact with the second barrier metal pattern, and
wherein the first metal pattern is in direct contact with the second metal pattern.

6. The semiconductor package of claim 5, wherein a top surface of the first barrier metal pattern and a top surface of the second barrier metal pattern are coplanar with the top surface of the redistribution dielectric layer and the top surface of the base dielectric layer.

7. The semiconductor package of claim 1, wherein
the redistribution dielectric layer and the base dielectric layer include a same dielectric material, and
the plurality of redistribution chip pads and the plurality of upper coupling pads include a same metallic material.

8. The semiconductor package of claim 1, wherein the redistribution dielectric layer and the base dielectric layer include a photosensitive polymer layer.

9. The semiconductor package of claim 1, wherein
the molding layer has a bottom surface in contact with the top surface of the redistribution substrate, and
the bottom surface of the molding layer is coplanar with the top surfaces of the plurality of redistribution chip pads and with the top surface of the redistribution dielectric layer.

10. The semiconductor package of claim 1, wherein a corresponding one of the plurality of redistribution chip pads and a corresponding one of the plurality of upper coupling pads are connected into a single body without an interface between the corresponding one of the plurality of redistribution chip pads and the corresponding one of the plurality of upper coupling pads.

11. The semiconductor package of claim 1, wherein the first maximum width is different from the second maximum width.

12. The semiconductor package of claim 1, wherein
portions of the plurality of redistribution chip pads are in contact with the top surface of the base dielectric layer, and
portions of the plurality of upper coupling pads are in contact with the top surface of the redistribution dielectric layer.

13. A semiconductor package, comprising:
a redistribution substrate including a base dielectric layer and a plurality of upper coupling pads in the base dielectric layer, top surfaces of the upper coupling pads being coplanar with a top surface of the base dielectric layer; and
a semiconductor chip on the redistribution substrate and including a redistribution dielectric layer and a plurality of redistribution chip pads in the redistribution dielectric layer, top surfaces of the plurality of redistribution chip pads being coplanar with a top surface of the redistribution dielectric layer,
wherein the top surface of the redistribution dielectric layer is bonded to the top surface of the base dielectric layer,
wherein the plurality of redistribution chip pads are bonded to the plurality of upper coupling pads,
wherein the plurality of redistribution chip pads and the plurality of upper coupling pads include a same metallic material, and
wherein the redistribution dielectric layer and the base dielectric layer include a photosensitive polymer layer.

14. The semiconductor package of claim 13, wherein an interval between adjacent ones of the plurality of redistribution chip pads is less than a width of each of the plurality of redistribution chip pads.

15. The semiconductor package of claim 13, wherein
each of the plurality of redistribution chip pads has an inclined first sidewall,
each of the plurality of upper coupling pads has an inclined second sidewall, and
the plurality of redistribution chip pads are mirror-symmetrical to the plurality of upper coupling pads.

16. The semiconductor package of claim 13,
wherein each of the plurality of redistribution chip pads includes a first metal pattern and a first barrier metal pattern,
the first metal pattern is in the redistribution dielectric layer, and
the first barrier metal pattern has a uniform thickness and covers a bottom surface of the first metal pattern and a sidewall of the first metal pattern, and
wherein each of the upper coupling pads includes a second metal pattern and a second barrier metal pattern,
the second metal pattern is in the base dielectric layer, and
the second barrier metal pattern has a uniform thickness and covers a bottom surface the second metal pattern and a sidewall of the second metal pattern.

17. The semiconductor package of claim 13, further comprising:
a molding layer on the redistribution substrate, wherein
the molding layer covers the semiconductor chip, and
a sidewall of the molding layer is aligned with a sidewall of the redistribution substrate.

18. A semiconductor package, comprising:
a redistribution substrate including a base dielectric layer and a plurality of upper coupling pads in the base dielectric layer; and
a semiconductor chip on the redistribution substrate, the semiconductor chip including a semiconductor substrate that includes a plurality of chip pads, a protection layer that covers a top surface of the semiconductor substrate, a redistribution dielectric layer on the protection layer, and a plurality of redistribution chip pads that penetrate the redistribution dielectric layer and the protection layer and are connected to the plurality of chip pads,
wherein the base dielectric layer and the redistribution dielectric layer are in direct contact with each other,
wherein the plurality of redistribution chip pads and the plurality of upper coupling pads are in direct contact with each other,
wherein each of the plurality of redistribution chip pads has an inclined sidewall and each of the plurality of upper coupling pads has an inclined sidewall,
wherein each of the plurality of redistribution chip pads has a first maximum width at a bonding surface between the redistribution substrate and the semiconductor chip, and
wherein each of the plurality of upper coupling pads has a second maximum width at the bonding surface between the redistribution substrate and the semiconductor chip.

19. The semiconductor package of claim 18, wherein
the protection layer includes a silicon oxide layer, and
the redistribution dielectric layer and the base dielectric layer include a photosensitive polymer layer.

20. The semiconductor package of claim 18, wherein an interval between adjacent ones of the plurality of redistribution chip pads is less than a width of each of the plurality of redistribution chip pads.

21.-25. (canceled)
